(19) United States
(12) Patent Application Publication
(10) Pub. No.: US 2010/0288343 A1
(43) Pub. Date: Nov. 18, 2010

(54) Nucleic acid-based photovoltaic cell

(75) Inventors: Gregory A. Sotzing, Storrs, CT (US); Yogesh J. Ner, Willimantic, CT (US)

Correspondence Address: JOHN S. PRATT, ESQ;KILPATRICK STOCKTON, LLP, 1100 PEACHTREE STREET, SUITE 2800, ATLANTA, GA, 30309, US

(73) Assignee: University of Connecticut, Farmington, CT (US)

(21) Appl. No.: 12/800,583

(22) Filed: May 18, 2010

Related U.S. Application Data
(60) Provisional application No. 61/179,203, filed on May 18, 2009.

(51) Int. Cl. H01L 31/02; B32B 37/02

(52) U.S. Cl. 136/252; 156/60

(57) ABSTRACT

Photovoltaic cells containing nucleic acid materials and methods of production and use are provided. The nucleic acid materials have photovoltaic donor and acceptor molecules incorporated therein and define a spatial organization and orientation for these molecules that inhibits recombination of excitons and promotes efficiency in the photovoltaic cell. Preferred nucleic acid materials contain nucleic acid molecules complexed with ionic surfactants and are in the form of films, fibers, nanofibers, or non-woven meshes.

### CROSS REFERENCE TO RELATED APPLICATIONS

This application claims the benefit of U.S. Provisional Application No. 61/179,203, filed May 18, 2009, which is hereby incorporated by reference.

### FIELD

This application relates to photovoltaics and more particularly to a nucleic acid-based photovoltaic cell.

### BACKGROUND

Solar power technology, or photovoltaics, is a technology that uses solar cells or solar arrays to convert light from the sun into solar-generated electricity. The manufacture and use of photovoltaic cells has expanded significantly in recent years in several countries including Germany, Japan and the United States due to economic incentives and advantages such as the absence of pollution during use, low operating costs, and minimal maintenance.

Solar-generated electricity is particularly useful in locations where grid connection or fuel transport is difficult, costly, or impossible such as on satellites, islands, remote locations, and ocean vessels. Photovoltaics can provide a supplemental source of electricity during times of peak demand to reduce grid loading and eliminate the need for local battery power.

Virtually all commercial photovoltaic cells are based on silicon. The most efficient cells use crystalline or polycrystalline silicon as the photoactive medium. These cells are expensive to manufacture. Photovoltaic cells that are made using amorphous silicon are cheaper, but less efficient. Although silicon solar cells do not create pollution under operation, their manufacture is a serious source of pollution such that some environmentalists no longer consider photovoltaic energy conversion to be a “green” technology. Some photovoltaic cells include cadmium, which is a highly toxic metal that is harmful to animal life and difficult to remove from the environment. Moreover, the disposal of cadmium also presents problems due to its toxicity.

Organic photovoltaic cells are considered to be cost effective alternatives to currently available silicon-based solar cells. Organic photovoltaics offer processing advantages, such as a simple roll-to-roll fabrication, which makes them suitable for large area fabrication. However, organic photovoltaic cells suffer from low quantum efficiencies. In general, organic photovoltaic cells are constructed in a layer-by-layer fashion using a chemical vapor deposition technique that allows formation of nanometric thin films of participating molecules. These solar cells have alternating layers of participating donor and acceptor molecules and electrodes. Generally, these alternating layers include one or more of a transparent electrode layer, a donor molecule layer, an acceptor molecule layer, and a metal electrode layer. Some solar cells may include one or more of each type of layer. Solar cells having donor and acceptor molecules in the same layer are known by those skilled in the art as bulk heterojunction solar cells.

Polymer photovoltaic cells have the same basic configuration as organic small molecule photovoltaic cells, but unlike small molecule based cells, polymer photovoltaic cells can be solution processed. Like organic small molecule cells, polymer photovoltaic cells can be configured for bulk heterojunction. Polymeric materials can also have alternating blocks of donor and acceptor molecules. Block copolymers can have a regular phase segregation that leads to a regular morphology allowing for spatial organization of donor and acceptor dyes within a length scale commensurate with exciton diffusion length. Block copolymers often require tailored synthesis, and donor and acceptor molecules are typically covalently attached to a polymeric backbone. The synthesis of block copolymers requires heat treatment for better phase separation. However, the highest known efficiency of a polymeric photovoltaic cell is about 4.8%.

Titanium dioxide-based photovoltaic cells remain an important technological innovation in photovoltaics. These cells have higher conversion efficiencies (about 10%), but also have disadvantages. For example, these cells use liquid electrolytes, which limit their long term outdoor use. Recent advances such as liquid crystalline electrolytes and gel electrolytes may improve durability, but practical use of these cells remains a technological challenge.

Therefore, what is needed are photovoltaic cells that do not pollute the environment during use or disposal, are cost effective, and that exhibit high efficiency and durability with minimal maintenance.

### SUMMARY

A nucleic acid material for use in photovoltaic cells, a method of making the nucleic acid material, a method of using the nucleic acid material to produce electrical energy from electromagnetic radiation, a photovoltaic cell composed of the nucleic acid material, and a method of making the nucleic acid-based photovoltaic cell are described herein.

The photovoltaic cells provided herein contain an anode layer, a nucleic acid layer, and a cathode layer, wherein the nucleic acid layer lies between and in direct or indirect contact with both the anode layer and the cathode layer. The photovoltaic cell may also include intermediate layers, such as electron blocking layers or hole blocking layers. These intermediate layers ensure that the electrons flow in one direction in the device and allow the device to function more efficiently. In some embodiments, one or more intermediate layers lie between the nucleic acid layer and the anode layer and/or between the nucleic acid layer and the cathode layer. In at least these embodiments, the nucleic acid layer is in indirect contact with the anode layer and/or the cathode layer respectively. The nucleic acid layer includes a plurality of donor and acceptor molecules that are spaced and oriented within a nucleic acid material in an arrangement that allows the photovoltaic cell to convert electromagnetic radiation into electrical energy.

The nucleic acid material contains one or more nucleic acid molecules. Photovoltaic cells containing the nucleic acid material described herein enable high donor and/or acceptor loading, enhanced energy transfer between donors and acceptors due to their relative orientation and organization in the nucleic acid material and high electron mobility for improved photovoltaic efficiency.

Nucleic acids exhibit features required for an efficient optoelectronic material including nanometer scale structural geometry, self-assembly, self-replication, and controversially discussed/reported one-dimensional electron conduction. Nucleic acids have unique abilities to interact with a variety of molecules through multiple mechanisms. These interactions lead to materials with well-defined nanoscale morphologies that are suitable for a variety of applications. Nucleic acids impose a defined spatial organization and orientation on the small molecules with which they interact and simultaneously prevent aggregation of these molecules.

In one embodiment a nucleic acid material having a plurality of donor and acceptor molecules incorporated therein is provided wherein the donor and acceptor molecules are photovoltaic dye molecules, or chromophores. These dye molecules have a 3-dimensional organization fixed by the nucleic acid material.

A preferred nucleic acid molecule in the nucleic acid material provided herein is deoxyribonucleic acid (DNA). Another preferred nucleic acid is double-stranded ribonucleic acid (RNA).

It has been discovered, as described herein, that nucleic acid materials can help to improve the efficiencies of photovoltaic cells due to their material properties and their ability to interact with a wide range of polyaromatic hydrocarbons as well as with other donor and acceptor molecules. More specifically, nucleic acid materials can reduce recombination of excited charges (i.e. excitons) by placing donor and acceptor molecules in close proximity (i.e. within the exciton diffusion length) of each other and by functioning as hole injection layers. Nucleic acid materials can also improve light harvesting. Additionally, like polymeric photovoltaic cells, nucleic acid materials have the advantage of being solution processable. Unlike conventional polymers, however, nucleic acid materials impose a defined and fixed spatial organization on the photovoltaic donor and acceptor molecules, which increases the photostability of the dyes and improves the efficiency of the photovoltaic cell. Such cells may also exhibit enhanced durability.

The nucleic acid material may be in the form of a nucleic acid molecule complexed with an ionic surfactant or a lipid with an ionic head group to improve processability. The preferred surfactant is a cationic surfactant. The preferred lipid is a lipid with a cationic head group. These nucleic acid materials are soluble in organic solvents and can be processed into thin films (e.g. by dip casting or spin casting) or into fibers, nanofibers, or non-woven meshes (e.g. by electrospinning) using techniques known to those skilled in the art. The processed complexes exhibit excellent thermal stability and transparency. Nucleic acid-surfactant complexes are also known to form a regular arrangement of alternate layers of nucleic acid and surfactant through nucleic acid self-assembly. The coordination between a nucleic acid and a surfactant results in a lamellar structure of aligned parallel nucleic acid sandwiched between surfactant layers.

Thus, described herein is a nucleic acid material for use in a photovoltaic cell, and more particularly a nucleic acid material capable of interacting with and enhancing the photostability of a wide range of photovoltaic donor and acceptor molecules.

In an embodiment, the nucleic acid material is a nucleic acid-ionic surfactant complex.

Also described herein is a photovoltaic cell containing the nucleic acid material provided herein.

Further described herein is a method of making a photovoltaic cell wherein a nucleic acid material aids the processing of the cell.

In some embodiments, the nucleic-acid based material is in the form of a film, a fiber, a nanofiber, or a nonwoven mesh.

Other systems, methods, processes, devices, features, and advantages associated with the nucleic acid materials described herein will be or will become apparent to one with skill in the art upon examination of the following drawings and detailed description. All such additional systems, methods, processes, devices, features, and advantages are intended to be included within this description, and are intended to be included within the scope of the present invention.

### BRIEF DESCRIPTION OF THE FIGURES

The patent or application file contains at least one drawing executed in color. Copies of this patent or patent application publication with color drawing(s) will be provided by the Office upon request and payment of the necessary fee.

FIG. 1 is a schematic of a cationic surfactant complexed with DNA.

FIG. 2 is a 2-dimensional representation of DNA-surfactant self assembly.

FIG. 3 is a schematic showing the lamellar structure of DNA and a cationic surfactant.

FIG. 4 is an FESEM image of electrospun DNA-CTMA fibers.

FIG. 5 is an X-ray diffraction pattern of a self-standing electrospun DNA-CTMA nanofiber mesh.

FIG. 6 is a normalized emission spectra and UV-visible absorption of nanofibers of DNA-CTMA-Cm102 (donor, maximum at 430 nm) and DNA-CTMA-Hemi22 (acceptor, maximum at 560 nm), respectively.

FIGS. 7A-B are fluorescence microscopy images of electrospun nanofibers of DNA-CTMA-donor (7A) and DNA-CTMA-multiple dye with acceptor:donor molar ratio 1:5 (7B).

FIG. 8 is a series of quenching curves for multi-dye doped DNA-CTMA nanofibers with varying ratios of acceptor to donor molecules.

FIG. 9 is a graph showing FRET efficiency plotted against acceptor to donor ratio.

FIG. 10 is a graph showing the quenching behavior of the α,107 -sexithiophene in presence of electron acceptor buckminsterfullerene C₆₀.

FIGS. 11A-B are graphs showing the comparative photostability of DNA (11A) and PMMA (11B) films prepared with equivalent amounts of Hemi 22.

FIG. 12 is a schematic showing the band structure of a DNA based photovoltaic cell.

### DETAILED DESCRIPTION

A nucleic acid material and method of making the nucleic acid material are provided. Also provided are a photovoltaic cell containing the nucleic acid material, a method of making a photovoltaic cell, and a method of using the nucleic acid material to produce electrical energy from electromagnetic radiation.

During operation of a photovoltaic cell, incident light is absorbed by a donor molecule. This absorption creates a photoexciton (electron-hole pair). The photoexciton is generated due to the excitation of an electron from the highest occupied molecular orbital (HOMO) of the donor molecule across the band gap to the lowest unoccupied molecular orbital (LUMO) of the donor molecule. The excited electron can either recombine with the hole or can diffuse to the donor/acceptor interface where splitting of the Coulomb bound species (i.e. separation of electrons and holes) may be achieved. This splitting is possible if donor and acceptor materials are selected such that the LUMO-acceptor energy level is below the LUMO-donor energy level. In this case the electron crosses the barrier from the donor region to the acceptor region and continues toward the cathode while the hole travels toward the anode. At the electrodes, in order for the holes and electrons to cross the semiconductor-metal (Schottky) barrier, it is crucial that the work functions of the selected electrodes (i.e. the minimum energy required to remove an electron from that metal) match or overlap the respective levels of the active material, i.e. the HOMO of the donor molecule matches or overlaps with the anode's work function, and the LUMO of the acceptor molecule matches or overlaps with the cathode's work function. One method for matching the barrier between electrode and active layer, e.g. donor or acceptor layer, involves the use of additional layers such as a hole injection layer on the anode and an electron injection layer on the cathode.

The efficiencies of organic photovoltaic cells can be improved by reducing recombination of excitons and improving light harvesting. The major reason for low conversion efficiencies of organic photovoltaic cells is recombination of the excitons generated by incident light. The exciton diffusion distance is limited to a few nanometers (10-20 nm), so an exciton generated more than 20 nm from the donor/acceptor interface is likely to recombine before diffusing to the interface and crossing the barrier. One way to reduce recombination is to reduce the separation of the donor and acceptor molecules to within the exciton diffusion distance. Bulk heterojunction technology has had success in layering the donor and acceptor molecules such that they are sufficiently close to prevent recombination. Annealing may improve the morphology. However, upon annealing, these layers often tend to separate and form segregated domains, which reduces efficiencies of the photovoltaic cells by several orders.

The photovoltaic cell provided herein contains an anode, a nucleic acid material, and a cathode, wherein the nucleic acid layer lies between and in direct or indirect contact with both the anode and the cathode. The photovoltaic cell may also include intermediate layers, such as electron blocking layers or hole blocking layers. These intermediate layers ensure that the electrons flow in one direction in the device and allow the device to function more efficiently. In some embodiments, one or more intermediate layers lies between the nucleic acid layer and the anode layer and/or between the nucleic acid layer and the cathode layer. In at least these embodiments, the nucleic acid layer is in indirect contact with the anode layer and/or the cathode layer respectively. The nucleic acid layer includes a plurality of donor and acceptor molecules that are spaced and oriented within a nucleic acid material in an arrangement for converting electromagnetic radiation into electrical energy. The nucleic acid material contains one or more nucleic acid molecules.

Preferably, the donor and acceptor molecules are embedded within the nucleic acid material or associated therewith and are donor-acceptor pairs suitable for use in a photovoltaic cell. In embodiments, the donor and/or acceptor molecules are intercalated with the nucleic acid material, groove-bound to the nucleic acid material, and/or ionically bound to the nucleic acid material. In embodiments, the donor molecules can absorb ultraviolet radiation, near infrared radiation, infrared radiation, and/or visible radiation. In embodiments, the donor molecules can absorb solar radiation.

The nucleic acid material described herein may further include an ionic surfactant or a lipid with an ionic head group. The preferred ionic surfactant is a cationic surfactant. The preferred lipid is a lipid with a cationic head group. The nucleic acid molecules may interact with the surfactant in the nucleic acid material to form a nucleic acid-surfactant complex. In some embodiments, the nucleic acid material is in the form of a film, fiber, nanofiber, or non-woven mesh. Some embodiments are produced by dip casting, spin casting or electrospinning.

The nucleic acid material provided herein is biodegradable and biocompatible, poses little or no environmental risk, and is useful for the manufacture of a photovoltaic cell having improved efficiency. In addition, the spatial organization and orientation of these molecules inhibits recombination of excitons and promotes efficiency when employed in the photovoltaic cell.

Photovoltaic cells containing the nucleic acid material described herein enable high dye loading, enhanced energy transfer between donors and acceptors due to their relative orientation and organization in the nucleic acid material, and high electron mobility for improved photovoltaic efficiency.

Photovoltaic cells as described herein can be used to produce electrical energy from electromagnetic radiation by irradiating at least one donor molecule in the photovoltaic cell, which places at least one electron of the donor molecule in an excited state. Thereafter, the excited electron is transferred from the donor molecule to an acceptor molecule and from the acceptor molecule to a cathode. The transfer of the excited electron from the acceptor molecule to the cathode produces electrical energy.

In embodiments the electromagnetic radiation is in the form of ultraviolet radiation, near infrared radiation, infrared radiation, or visible radiation. In embodiments the electromagnetic radiation is solar radiation.

### Definitions

As used herein, the term “nucleic acid” refers to DNA, RNA, and derivatives thereof, including, but not limited to, cDNA, gDNA, msDNA and mtDNA, mRNA, hnRNA, tRNA, rRNA, aRNA, gRNA, miRNA, ncRNA, piRNA, shRNA, siRNA, snRNA, snoRNA, stRNA, ta-siRNA, and tmRNA, as well as artificial nucleic acids including, but not limited to, peptide nucleic acid (PNA), glycol nucleic acid (GNA), threose nucleic acid (TNA), morpholino and locked nucleic acid (LNA).

The terms “a,” “an,” and “the” as used herein include the plural referents unless expressly and unequivocally limited to one referent.

The term “dye” as used herein is a coloring agent. Most dyes tend to be organic in nature and are soluble.

As used herein, the term “chromophore” is defined as the group of atoms within a dye molecule that is responsible for the electronic transition and/or the dye molecule itself. Thus, the terms chromophore and dye as used herein are synonymous and interchangable. The chromophore is the portion of the dye molecule that gives the dye color. A chromophore that emits light through fluorescence is a fluorophore.

### Nucleic Acid Material

Nucleic acids exhibit features required for an efficient optoelectronic material including nanometer scale structural geometry, self-assembly, self-replication, and controversially discussed/reported one-dimensional electron conduction. Nucleic acids can form complexes with a wide variety of molecules through intercalation, groove-binding, and ionic interactions. Because of the intrinsic lattice structure of nucleic acids, guest molecules are isolated and have defined spatial orientations. Nucleic acids can also complex with ionic surfactants and lipids with ionic head groups. Nucleic acids are natural materials and renewable resources that are both biocompatible and biodegradable.

The nucleic acid material allows simultaneous encapsulation of multiple donor and acceptor molecules by multiple mechanisms and imposes a defined spatial organization and orientation on those small molecules. Such an arrangement is required for efficient energy transfer to occur. This increased level of organization is an improvement over other dye-based solar cells. It also enables a high dye loading of up to 50%. The defined and constricted spatial positions of the donor and acceptor molecules within the nucleic acid matrix enhance the photostabilities of the donor and acceptor molecules. For example, DNA complexes can accommodate donor and acceptor molecules without aggregation until all DNA grooves incorporate donor and acceptor molecules. Theoretically, loadings up to 30% by weight are possible depending upon the molecular weight of the donor and acceptor molecules used. This is an advantage over conventional polymers such as polymethylmethacrylate (PMMA) and polyvinyl alcohol (PVA) because those conventional polymers lack an organized internal structure and, therefore, cannot prevent embedded donor and acceptor molecules from interacting at higher concentrations which ultimately results in self-quenching due to aggregation.

A preferred nucleic acid molecule for use in the nucleic acid material provided herein is DNA. DNA is a natural material and a renewable resource. DNA has unique chemical and materials properties including the ability to interact with a wide variety of small molecules through multiple mechanisms such as intercalation, groove binding, and ionic interactions. Another preferred nucleic acid molecule is double stranded RNA, which has similar abilities to interact with molecules.

### Nucleic Acid Material Including Surfactant

It is very difficult to process nucleic acid solutions in their native form due to strong intermolecular interactions and interwinding. To overcome these problems, the nucleic acid material provided herein may be complexed with one or more molecules of an ionic surfactant or a lipid with an ionic head group, to improve processability. These complexes are soluble in organic solvents and can easily be processed into thin films (e.g. by dip casting or spin casting) or into fibers, nanofibers, or non-woven meshes (e.g. by electrospinning). The processed complexes have excellent thermal stability and transparency. Nucleic acid-surfactant complexes are also known to form a regular arrangement of alternate layers of nucleic acid and surfactant through nucleic acid self-assembly.

The preferred ionic surfactant is a cationic surfactant. The preferred lipid is a lipid with a cationic head group. Exemplary cationic surfactants are quaternary ammonium cations or salts and include, but are not limited to, cetyl trimethylammonium (CTMA) chloride (also referred to as hexadecyl trimethylammonium chloride), cetylpyridinium chloride (CPC), polyethoxylated tallow amine (POEA), benzalkonium chloride (BAC), benzethonium (BZT) chloride, dioleoyl phosphatidylethanolamine (DOPE), cetyl trimethylammonium (CTAB) bromide, dioleoyltrimethylammonium propane (DOTAP), and dioctadecyldimethylammonium bromide (DODAB).

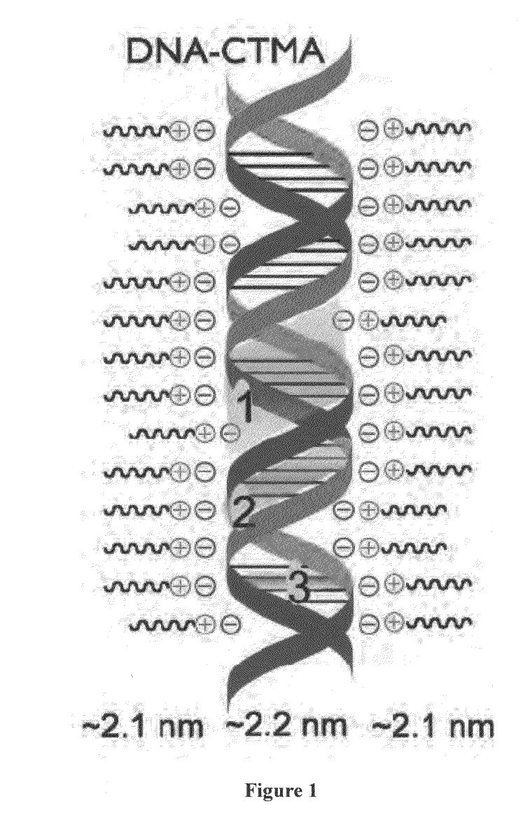

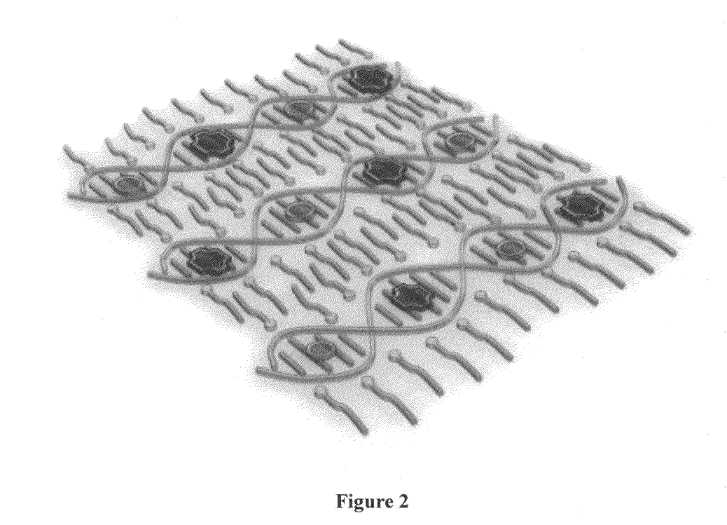

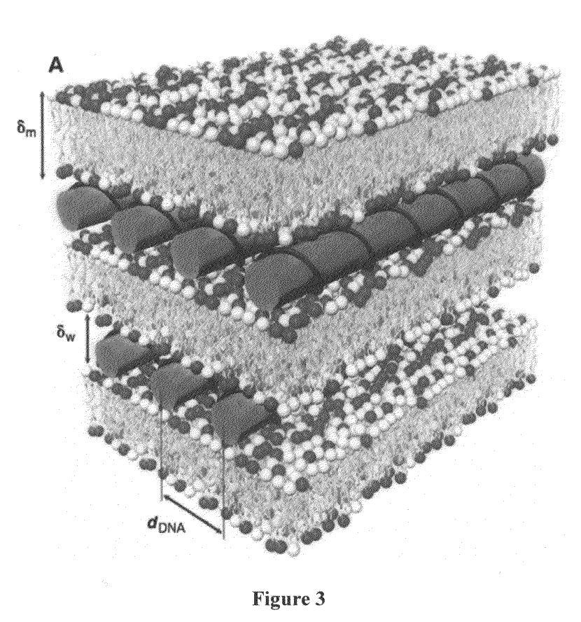

The coordination between a nucleic acid and a surfactant can result in a lamellar structure of aligned parallel nucleic acid sandwiched between surfactant layers. As an example, this coordination is shown in FIGS. 1-3 for DNA-CTMA. FIG. 1 is a schematic showing cationic CTMA complexed with DNA. (Radler, J. O., et al., Science 1997, 275(5301), 810-14.) Distances shown in FIG. 1 are (1) major groove (2.1 nm), (2) minor groove (2.2 nm), and (3) distance between ladder units (2.1 nm). FIG. 2 is a schematic showing a 2D representation of DNA self assembly. FIG. 3 is a schematic showing the lamellar structure of DNA (rods) and the cationic surfactant DOPE. (Yu, Z., et al. Appl. Opt., 2007, 46(9): p. 1507-13).

As an example, in one embodiment a surfactant-nucleic acid complex may be prepared by addition of a surfactant to a nucleic acid. In one embodiment, the complex may be prepared by slow stoichiometric addition of the cationic surfactant CTMA chloride to a nucleic acid in an aqueous concentration of 1% w/w to produce a nucleic acid-CTMA complex. The resulting precipitate can then be filtered, cleaned, and dried in accordance with methods well known to those skilled in the art.

The nucleic acid material containing surfactant, as described herein and also referred to as the nucleic acid-surfactant complex, has advantageous properties that make it suitable for a variety of applications. The cationic surfactant that complexes with the nucleic acid has a cationic head and a long alkyl chain tail. The tails of these molecules can be designed to carry functional groups including but not limited to donor and acceptor molecules and other active functional groups. Additionally, cationic surfactants are known to be antimicrobial and antifungal, thus the material of the invention also serves the purpose of an antimicrobial/antifungal material. Furthermore, nucleic acid-surfactant complexes are highly optically transparent (up to 99%) and have very low background fluorescence, so they are suitable for optical applications. Finally, the nucleic acid-surfactant complex described herein provides a biocompatible host matrix.

The nucleic acid-surfactant complex provides ample opportunities for small molecule interaction, either with the nucleic acid or with the surfactant component.

Small molecules can associate with the nucleic acid-surfactant complex in a variety of ways including intercalation, groove-binding, and through ionic interactions. Multiple structural phases of the nucleic acid-surfactant complex provide a variety of specific nano-environments that can sequester small molecules. For example, the polar nucleic acid phase provides both ionic and dispersive bonding opportunities, while the surfactant phase accommodates non-polar and hydrophobic molecules. The implication for photovoltaic technologies is that populations of donor and acceptor dyes can be isolated from one another within the same matrix, thereby allowing higher loading levels than are possible with other matrix materials. The variety of opportunities for interactions between small molecules and the nucleic acid-surfactant complex allows design of antenna systems wherein a wide range of the solar spectrum can be harvested using a single layer. In a typical photoantenna system, multiple small organic molecules can be used that are able to absorb light at different levels of the energy spectrum, thereby providing a better match with the solar spectrum and improving light harvesting.

The small molecules can associate with the nucleic acid before or after the nucleic acid-surfactant complex is formed. If the molecules associate with the nucleic acid-surfactant complex after it is formed, they may associate with the complex either before processing while the complex is in solution or after processing while the complex is in the form of a film or fiber. Thus, films and fibers formed from the nucleic acid-surfactant complexes can be used to absorb small molecules to remove those molecules from a medium such as air or a solvent. Nucleic acid-surfactant complexes have particular affinity for aromatic molecules including, but not limited to, the dyes disclosed herein.

A vast variety of donor and acceptor molecules can interact with nucleic acids. This provides opportunities to construct a photovoltaic cell from a broad range of donor and acceptor molecules. A particular donor or acceptor molecule's solubility will determine the methods by which a homogeneous matrix of a nucleic acid and that donor or acceptor molecule may be produced. For example, if the donor or acceptor molecule is water soluble the donor or acceptor molecule may be added to an aqueous DNA solution before the DNA is complexed with a cationic surfactant. If the donor or acceptor molecule is soluble in alcohol and/or chloroform the donor or acceptor molecule may be added to a solution of a DNA-surfactant complex in alcohol or chloroform or a mixture thereof. If the donor or acceptor molecule is soluble in a solvent other than water, alcohol, or chloroform a DNA-surfactant complex may be processed into a preferred shape, e.g. film or fiber, and the processed DNA-surfactant complex may then be dipped into a solution of donor or acceptor molecules to produce the donor- or acceptor-DNA-surfactant matrix. If the donor or acceptor molecule is soluble in multiple solvents, these methods can be used alternatively or in combination.

### Donor and Acceptor Molecules

Preferred small molecules for interacting with the nucleic acid-surfactant complex include donor and acceptor molecules, also referred to herein as donor and acceptor chromophores or dyes. The efficiency of a photovoltaic cell depends in part upon the spacing and relative orientation of the donor and acceptor molecules. If donor and acceptor molecules are separated by a distance greater than the exciton diffusion distance, recombination of the excited electron and hole is more likely than diffusion of the electron to the acceptor molecule. A photovoltaic cell having donor and acceptor molecules spaced in this way would be less efficient than a photovoltaic cell wherein all the donor molecules are within the exciton diffusion distance of an acceptor molecule.

The efficiency of a photovoltaic cell is also related to, among other things, the concentration of the donor and acceptor molecules. At low concentrations energy transfer may not occur or will occur with low efficiency. At high concentrations, aggregation may inhibit or quench energy transfer. The unique properties of nucleic acids tend to sequester donor and acceptor molecules in such a way that their relative orientation and separation are locked in an arrangement which facilitates efficient energy transfer and allows higher loading of donor/acceptor molecules without detrimental aggregation. This arrangement cannot be duplicated in an amorphous polymer matrix.

The structure of nucleic acids provides a convenient matrix for photovoltaic donor and acceptor molecules which positions the donor and acceptor molecules in a constant relative spatial arrangement. This arrangement fixes both the distance between the donor and acceptor molecules and the relative orientation of the donor and acceptor molecules, which enhances photovoltaic efficiency. The nucleic acid matrix confines the photovoltaic dyes and stabilizes the dyes when they are in their excited state.

Donor and acceptor molecules for use in the disclosed photocells include any donor and acceptor molecules suitable for use in a photovoltaic cell. For example, the donor and acceptor molecules may include those known to those skilled in the art or described in relevant literature. Suitable donor and/or acceptor molecules include organic dyes and pigments, oligomeric compounds, and conducting polymers. For example, suitable organic dyes include, but are not limited to rhodamines; fluoresceines; cyanines; porphyrins; naphthalimides; perylenes; quinacridons; benzene-based compounds such as distyrylbenzene (DSB) and diaminodistylrylbenzene (DADSB); merocyanines, terylenes and sqyaraines and their derivatives; naphthalene-based compounds such as naphthalene and Nile red; phenanthrene-based compounds such as phenanthrene; chrysene-based compounds such as chrysene and 6-nitrochrysene; perylene-based compounds such as perylene and N,N′-bis(2,5-di-t-butylphenyl)-3,4,9,10-perylene-di-carboxyl amide (BPPC); coronene-based compounds such as coronene; anthracene-based compounds such as anthracene and bisstyrylanthracene; pyrene-based compounds such as pyrene; pyran-based compounds such as 4-(di-cyanomethylene)-2-methyl-6-(para-dimethylaminostyryl)-4H-pyran (DCM); acridine-based compounds such as acridine; stilbene-based compounds such as stilbene; oligothiophenes and thiophene-based compounds such as 2,5-dibenzooxazolethiophene, α-sexithiophene, α,ω-dialkylsexithiophene, and α,ω-dihexylsexithiophene; benzooxazole-based compounds such as benzooxazole; benzoimidazole compounds such as benzoimidazole; benzothiazole-based compounds such as 2,2′-(para-phenylenedivinylene)-bisbenzothiazole; butadiene-based compounds such as bistyryl(1,4-diphenyl-1,3-butadiene) and tetraphenylbutadiene; naphthalimide-based compounds such as naphthalimide; coumarin-based compounds such as coumarin; perynone-based compounds such as perynone; oxadiazole-based compounds such as oxadiazole; aldazine-based compounds; cyclopentadiene-based compounds such as 1,2,3,4,5-pentaphenyl-1,3-cyclopentadiene (PPCP); quinacridone-based compounds such as quinacridone and quinacridone red; pyridine-based compounds such as pyrrolopyridine and thiadiazolopyridine; Spiro compounds such as 2,2′,7,7′-tetraphenyl-9,9′-spirobifluorene; fullerene and arene compounds such as Buckminsterfullerene and pentacene, as well as their respective derivatives such as [6,6]-phenyl-C61-butyric acid methyl ester (PCBM); and metallic or non-metallic phthalocyanine-based compounds such as phthalocyanine (H₂Pc), zinc phthalocyanine and copper phthalocyanine. The donor/acceptor molecules can also be from the various organometallic complexes such as 3-coordination iridium complex having on a ligand 2,2′-bipyridine-4,4′-dicarboxylic acid, factris(2-phenylpyridine)iridium(Ir(ppy)₃), 8-hydroxyquinoline aluminum (Alq₃), tris(4-methyl-8-quinolinolate)aluminum(III) (Almq₃), 8-hydroxyquinoline zinc (Znq₂), (1,10-phenanthroline)-tris-(4,4,4-trifluoro-1-(2-thienyl)-butane-1,3-dionate), europium(III) (Eu(TTA)₃(phen)), 2,3,7,8,12,13,17,18-octaethyl-21H, and 23H-porphin platinum(II).

The choice of photovoltaic donor and acceptor molecules is important because intelligent selection of photovoltaic donor and acceptor molecules that can bind to nucleic acids by different mechanisms, e.g. intercalation or minor groove binding, can produce an optimum spacing between the dyes equal to the helical pitch of the nucleic acid (e.g. 3.4 nm for DNA). The spacing between donor and acceptor molecules is, therefore, smaller than the exciton diffusion length which is important for an efficient photovoltaic cell. A particular molecule may function as either a photovoltaic donor or a photovoltaic acceptor depending on the molecule with which it is paired. For a matched pair of photovoltaic donor and acceptor molecules the emission spectra of the donor molecule overlaps with the absorption spectra of the acceptor molecule.

In some embodiments the donor and acceptor molecules are selected such that the LUMO of the acceptor molecules is lower than the LUMO of the donor molecules.

### Electrospinning

For embodiments containing fibers of the nucleic acid material, particularly when the nucleic acid material is a nucleic acid-surfactant complex, the preferred method for making the fibers is by electrospinning. Electrospinning is a well characterized technique for making nanoscale fibers and non-woven meshes from polymeric materials. The process of electrospinning results in extremely high surface area and porosity non-woven meshes. As an example, nanofibers can be prepared by electrospinning using an orthogonal arrangement of a grounded collector and a syringe containing the nucleic acid material. The nucleic acid material can be electrospun into fibers that are suitable for absorbing donor and acceptor molecules or other small molecules. Alternatively, a donor or acceptor molecule may be introduced directly into the spin dope so that a nucleic acid material-chromophore matrix is formed prior to electrospinning.

Nucleic acid material-chromophore matrices have inherent properties of enhanced photostability and small molecule interaction, and electrospinning allows these properties to be simultaneously exploited. When used with conventional polymers, such as PMMA and PVA, electrospinning distributes donor and acceptor molecules homogeneously; however, the nucleic acid material-chromophore matrix described herein provides a fixed spatial distribution of molecules, formed prior to electrospinning, that both minimizes aggregation-based quenching and facilitates energy transfer.

The technique of electrospinning provides a morphology that can be exploited for both optical and sensor applications. Electrospun nanofibers amplify emission as a function of donor/acceptor alignment and fiber geometry and provide extremely high surface area for potential analyte interactions. Other advantages of this technique include: (i) easily controlled fiber dimension and morphology; (ii) simultaneous encapsulation of multiple donor and acceptor molecules or other molecules of interest; and (iii) inherent scalability. The complex, regular arrangement of nucleic acid and surfactant phases within electrospun nanofibers presents ample opportunities for the association of small molecules in discrete isolated sites.

### Film Deposition

The nucleic acid material provided herein is soluble in organic solvents. Nucleic acid material solutions are highly stable and thus, can be spin cast or dip cast. Typically, a 2% solution of a nucleic acid material, such as DNA-CTMA, in ethanol when spin cast at 2000 rpm for one minute yields films with thicknesses of 200 nm. The donor and acceptor molecules can also be directly added to these solutions. The DNA-CTMA solution consists of micelles of the CTMA encasing DNA macromolecules. These solutions also aid in dissolving insoluble organic donor and acceptor molecules.

### Improving the Efficiency of Photovoltaic Cells Using Nucleic Acid-Surfactant Complexes

### (a) Nucleic Acid-Surfactant as an Electron Blocking Layer (EBL):

Nucleic acid-surfactant complexes can serve as excellent electron blocking layers that can improve the efficiency of a photovoltaic cell by facilitating hole movement to the anode. For example, the HOMO of DNA-CTMA resides at 5.6 eV and the LUMO is at 0.9 eV. The HOMO level of the DNA-CTMA plays crucial role in deciding its EBL property. DNA-CTMA has been used as an electron blocking layer in devices such as organic light emitting diodes (OLEDs) and organic field effect transistors (OFETs). OLEDs fabricated with DNA as an EBL showed improved brightness and efficiency and OFETs constructed with DNA as an EBL showed a lowering of the operating gate voltage. In a similar fashion, DNA-CTMA can act as a complimentary layer in a photovoltaic cell for improving hole transport from the donor molecules to the anode. Apart from DNA-CTMA, other polymeric materials such as conductive polymers including polyvinylcarbazole, polysilane, aminopyrazine derivatives, polyethylenedioxythiophene (PEDOT) can be used as EBL.

### (b) Nucleic Acid-Surfactant Complexes for Better Light Harvesting:

Forster Resonance Energy Transfer (FRET) based energy harvesting antenna systems or luminescent concentrators can improve photon harvesting. Nucleic acid-surfactant complexes can also improve photon light harvesting. These nucleic acid-surfactant complexes have the ability to organize multiple dyes at the nanometer size scale, thereby improving energy transfer between the dyes. It is possible to design light harvesting antenna of the dyes which can absorb not only all visible light but which can also absorb light from the high energy NIR region of the solar spectrum. Nucleic acid-surfactant complexes can accommodate a very high loading of dyes without self aggregation. This level of loading is not possible without the defined and fixed orientation of dyes provided by the nucleic acid-surfactant complex. Thus, a nucleic acid-surfactant based system can accommodate multiple donors within a single matrix and can ultimately improve the light harvesting of the photovoltaic cell. The preferred composition of photoantenna consists of multiple donor molecules which have different absorption maxima from the solar spectrum.

### (c) Nucleic Acid-Surfactant for Organizing Donor and Acceptor Molecules:

The morphology of the photovoltaic cell dictates the mobility of the charge carriers and the likelihood of splitting the exciton. Since only excitons formed within the exciton diffusion distance of the interface of the donor and acceptor molecules are likely to cross the donor/acceptor barrier and proceed to the cathode, increasing the area of this interface results in better cell performance. This case is exemplified by the bulk heterojunction model which maximizes the area of the heterojunction. A continuous biphasic morphology is desired for an intimate bulk heterojunction and effective charge transport. Ideally, the sizes of the donor and acceptor domains should be 10-20 nm or less, in accordance with the exciton diffusion length. Percolated pathways should be available to reduce the possibilities of recombining the split exciton so the charge carriers may reach the electrodes. Additionally, solar cells based on thin films of block copolymer with donor-bridge-acceptor-bridge show improved performance over a corresponding donor/acceptor blend. The microstructure of DNA-CTMA can produce a similar effect if the donor and acceptor system is chosen carefully.

### Examples

This specification includes descriptions of embodiments of the invention and examples of processes and materials according to the present invention. These embodiments and examples are presented only for the purpose of illustration and description and are not intended to be exhaustive or to limit the invention to the precise forms disclosed.

### Electrospinninq of DNA-CTMA Complex

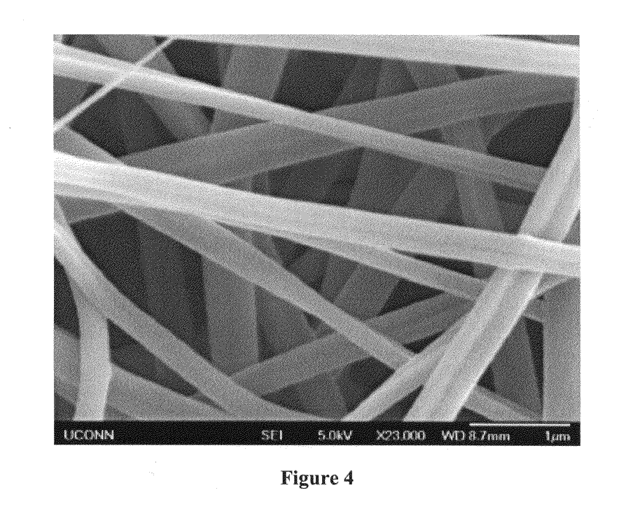

Electrospinning of DNA-CTMA nanofibers has been accomplished. In these nanofibers the native properties of DNA are preserved, e.g. intercalation ability. The combination of a high fiber aspect ratio, confined geometry, and donor and acceptor molecule intercalation results in a 100 fold enhancement in fluorescence yield compared to conventional polymer films such as polymethylmethacrylate doped with and equivalent dye concentration. FIG. 4 is an FESEM image of electrospun DNA-STMA nanofibers.

As a non-limiting example, electrospinning of the DNA-CTMA complex may be carried out as follows: An orthogonal collector platform is positioned below a syringe needle assembly containing the complex. A potential is applied to the syringe needle with the collector platform as a ground. Spin dopes are produced by dissolving the DNA-CTMA complex in 200 proof ethyl alcohol for a final concentration of 10% w/w. During electrospinning, the solution is passed through a blunt tip 18 G needle (ID 0.84 mm) placed at a distance of 15 cm above the collector. A constant potential of 15 kV is applied between the needle tip and the collector, and a flow rate of 0.8 ml/hr is maintained. The electrospinning is performed at ambient temperature. The spinning rate is controlled by adjusting the flow of the polymer solution using a motorized syringe pump and electrospinning is carried out for less than a minute. The electrospun fibers are collected on glass substrates placed on the grounded electrode, and dried at 60° C. in a vacuum oven for 30 minutes. As a result of this, fibers with an average fiber diameter in a range of from 250 nm to 350 nm were obtained.

### Crystallographic Studies

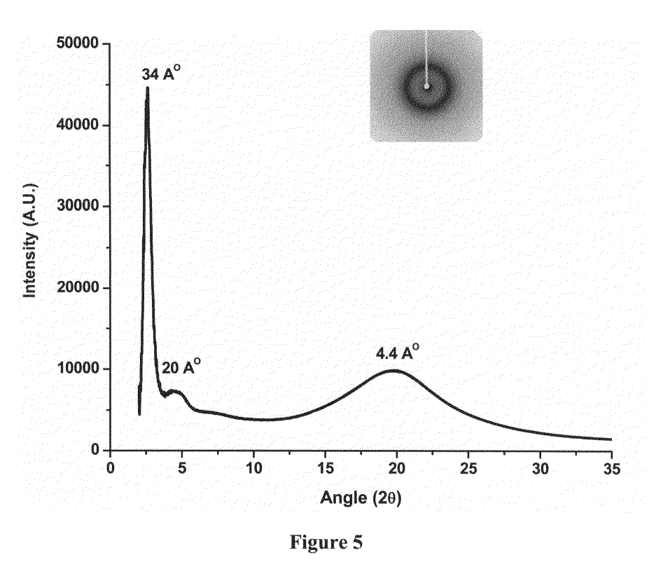

Nanofiber mesh was produced from a 10% (w/w) solution of DNA-CTMA in ethyl alcohol and chloroform in a ratio of 3:1 by weight. The nanofiber mesh was produced by electrospinning, which was carried out with an applied potential of 20 kV, a 15 cm distance between electrodes, and a flow rate of 0.8 mL/hr. FIG. 5 is an X-ray diffraction pattern of DNA-CTMA mesh. The dried DNA-CTMA self-standing electrospun nanofiber mesh had an average fiber diameter of 300 nm. The inset shows the WAXD pattern of the nanofibers. Circular reflection peaks at 34 Å and 4.4 Å are observed. The electrospun fibers in the non-woven mesh adopt a completely random orientation with respect to each other. The laminar distance between DNA strands is 34 Å, a value smaller than previously reported, which implies a more compact arrangement of DNA and CTMA phases in the nanofibers.

### Spectroscopic Studies

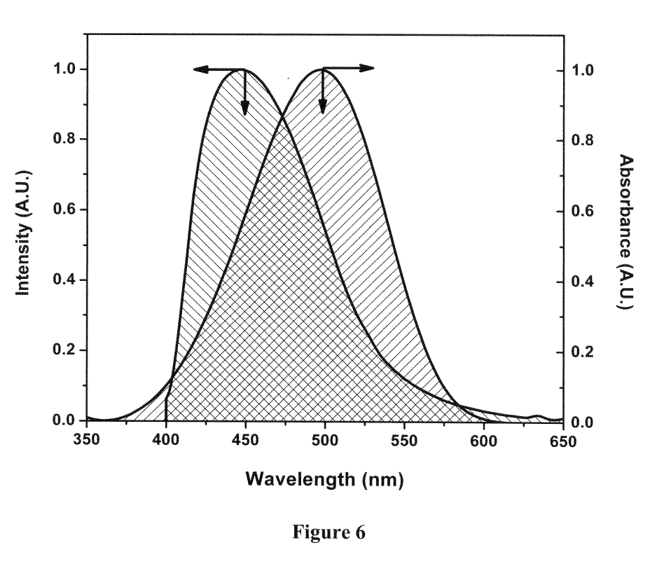

Spectroscopic studies were conducted on nanofibers of DNA-CTMA-Cm102 (donor, maximum at 430 nm) and DNA-CTMA-Hemi22 (acceptor, maximum at 560 nm), respectively. FIG. 6 is a normalized emission spectra and UV-Visible absorption of the nanofibers. The spectral overlap between the donor emission and acceptor absorption is shown in the doubly shaded region. The emission spectrum of both molecules is red-shifted in the DNA-CTMA as compared to PMMA. The Cm102 emission maxima in PMMA is 430 nm compared to 450 nm in DNA. In the case of Hemi 22, an emission maximum in PMMA of 560 nm is observed, compared to 600 nm in DNA. This indicates that the micro-environment around the molecules is highly polar and protic, and supports association of both molecules with the DNA phase.

### Fluorescence Microscopy

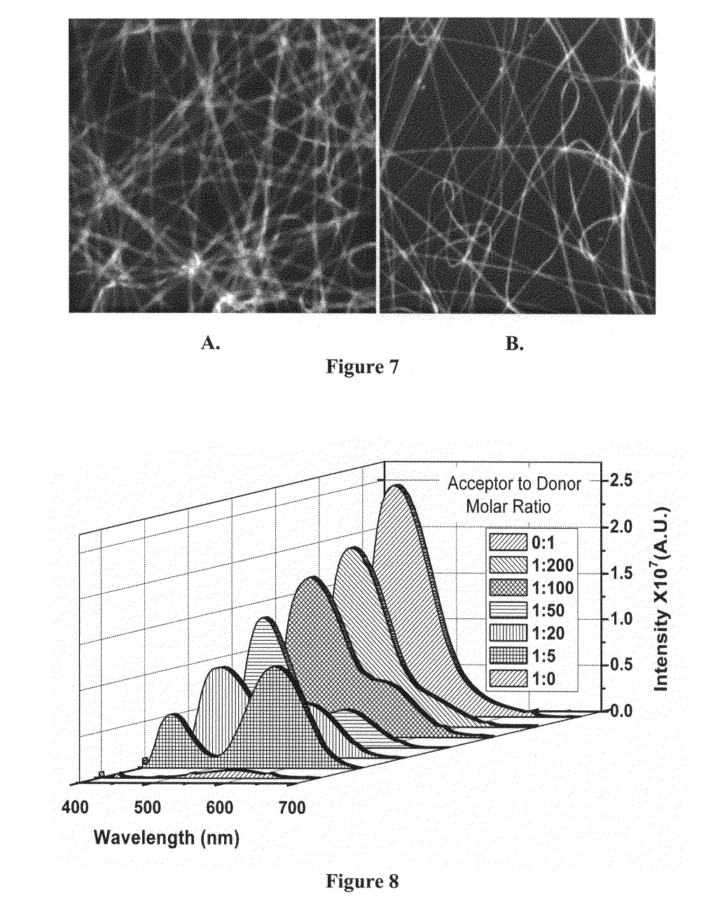

Donor doped and 1:5 acceptor:donor doped electrospun fibers were studied with fluorescence microscopy. FIGS. 7A-B are fluorescence microscopy images of excitation at 365 nm and emissions within the range of 400-700 nm. Fluorescence microscopy images clearly indicate the incorporation of the donor or acceptor within the nanofibers.

### Effectiveness of Energy Transfer in DNA-CTMA Matrix

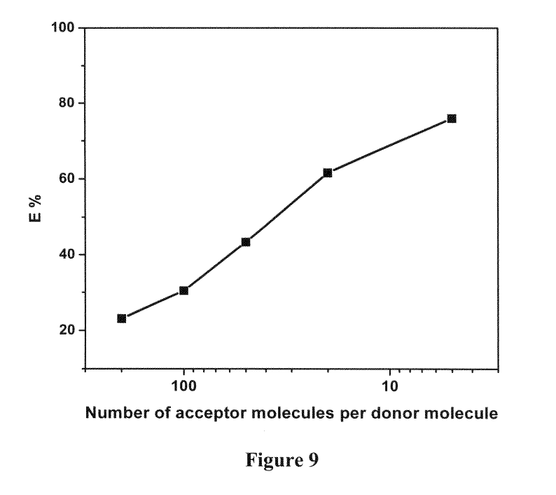

The effectiveness of the energy transfer in multi-doped DNA-CTMA nanofibers was studied by varying the ratio of acceptor to donor molecule. The ratio was varied between 1:200 and 1:5, and the concentration of donor dye was kept constant at 1 mole per 103 DNA base pairs to minimize self-quenching due to aggregation. FIG. 8 is a series of quenching curves for multi-dye doped DNA-CTMA nanofibers. In the presence of the acceptor (Hemi22), the donor (Cm102) shows quenching behavior, the magnitude of which increases at the donor emission maximum (˜450 nm) with increasing acceptor concentration. Thus, the donor emission intensity decreases as the acceptor concentration increases. The donor emission intensity decrease corresponds to an increase in acceptor intensity at ˜585 nm. The nanofiber fluorescence emission at an acceptor to donor ratio of 1:5 shows a distinct peak corresponding to acceptor emission maxima, whereas nanofibers containing only acceptor show no significant fluorescence with same excitation wavelength. This suggests efficient FRET between the donor and acceptor molecules within the DNA-CTMA nanofibers. FIG. 9 is a graph of FRET efficiency plotted against acceptor to donor ratio.

### Energy Transfer Studies with α,ω-Sexithiophene and Buckminsterfullerene

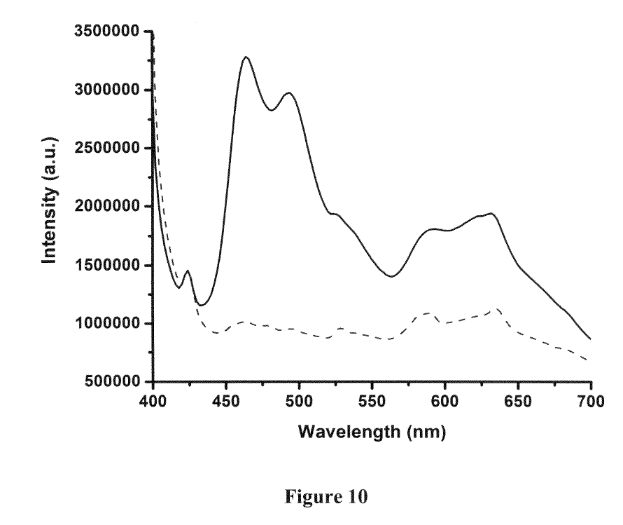

As an example, a 2% DNA-CTMA solution was made in ethanol and chloroform (1:1 w/w) mixture. α,ω-dihexylsexithiophene was added at 25 wt % of DNA. In one case a sample with buckminsterfullerene was added at the same level of loading as that of the α,ω-dihexylsexithiophene, giving a total loading of 50 wt % of donor and acceptor molecules. Both of these molecules were well dispersed in the presence of DNA-CTMA. The films were cast using spin coating, and very uniform films were obtained. FIG. 10 is an emission spectra of α,ω-dihexylsexithiophene in the presence (dashed line) and absence (solid line) of electron acceptor buckminsterfullerene C₆₀. Similar to earlier studies, the emission of the α,ω-dihexylsexithiophene was completely quenched by the electron acceptor.

### Photostability

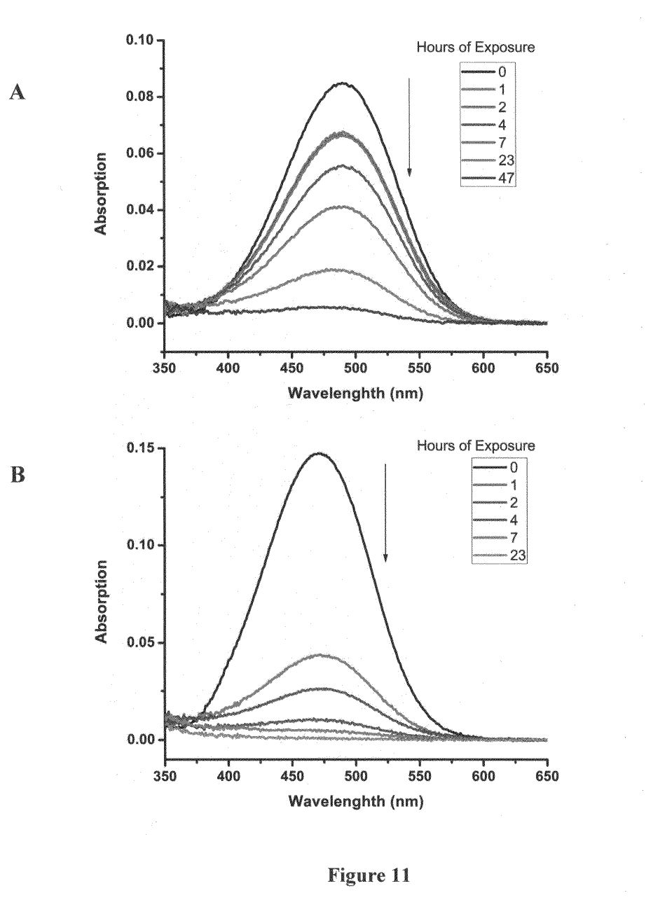

FIGS. 11A and B are graphs showing the comparative photostability of DNA and PMMA films prepared with equivalent amounts of Hemi 22 (i.e. 2.5% w/w). FIG. 11 shows the change in absorption upon exposure to UV light I=254 nm for DNA (A) and PMMA (B). The photostability experiments were carried out by exposing film to UV light I=254 nm in a laboratory scale UV chamber. As seen in FIG. 11, the DNA films exhibited remarkable improvement in the photostability compared to PMMA films. After 4 hours, the PMMA films showed loss of 93% of the initial absorption while DNA based films lost 34% of the initial absorption.

### DNA-Based Photovoltaic Cells

As an example, a photovoltaic cell as described herein may be made by combining a plurality of donor and acceptor molecules with a nucleic acid material, processing the nucleic acid material to form a film, fiber, nanofiber, or non-woven mesh on a substrate, placing a liquid electrolyte on the processed nucleic acid, placing metal-coated glass on the liquid electrolyte to create a photovoltaic cell, and sealing the photovoltaic cell. The metal may be any metal suitable for a photovoltaic cell. In embodiments, the metal is selected from gold, platinum, and combinations thereof. In some embodiments, the step of combining a plurality of donor and acceptor molecules with a nucleic acid material is accomplished by dissolving the nucleic acid material and the plurality of donor and acceptor molecules in a solvent to create a nucleic acid material-dye solution. In some embodiments, the step of processing the nucleic acid material is performed before the step of combining the plurality of donor and acceptor molecules with the nucleic acid material. In those embodiments, the step of combining the plurality of donor and acceptor molecules with the nucleic acid material may be accomplished by contacting the processed nucleic acid material with a solution of donor and acceptor molecules.

As one example, DNA-CTMA was dissolved in ethanol to yield a 4% w/w solution. Then tris-(bathophenanthroline)ruthenium (ii) chloride in chloroform was added to DNA-CTMA to yield 5% w/w of dye to DNA. The solution was spin cast at 2000 rpm for 2 min directly on ITO glass. Nal-I₂ liquid electrolyte was placed on top of the film, gold/platinum (70:30) coated glass was placed on top of the electrolyte, and device was sealed.

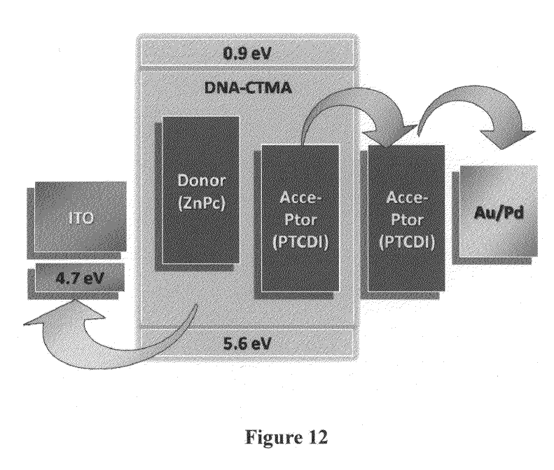

As another example, simple photovoltaic cell based on DNA was fabricated. The configuration of the cell was ITO/DNA-tris-(bathophenanthroline)ruthenium (ii) chloride/Nal-I₂ electrolyte/Gold:Palladium alloy as shown in FIG. 12. This cell showed a response to light which may have indicated that the cell was functioning as a photodiode. In another attempt, configurations were fabricated with zinc phthalocyanine and 3,4,9,10-perylenetetracarboxylic diimide to make a photovoltaic cell.

As another example, preparation of DNA cationic surfactant complex was carried out from 500 kDa salmon DNA. Briefly, 1% w/w aqueous solution of DNA was prepared, to which a stoichiometric amount of 1% w/w aqueous solution of CTMA was added over 4 hours. The resultant precipitate was washed with water and dried overnight en vacuo at 60° C. Coumarin 102 and 4-[4-(dimethylamino)styryl]-1-docosylpyridinium bromide were purchased from Sigma Aldrich and Exciton Inc, respectively.

Electrospinning was carried out with the spin dope consisting of 10% (w/w) DNA-CTMA in ethanol:chloroform (3:1, w/w). A homogeneous solution was obtained by heating at 60° C. for 30 minutes with constant stirring. Prior to electrospinning, the solution was stirred for another 5 minutes at room temperature. For dye doping, both solutions of both dyes were prepared prior to addition to DNA-CTMA. For consistency, the sequence of addition was kept as Cm102 (in ethanol) followed by Hemi22 (in chloroform). Electrospinning was performed at potential of 20 kV and the distance between the electrodes was maintained at 17 cm. The rate of spinning was controlled by adjusting flow rate using a motorized syringe pump, held constant value at 0.8 mL/hr. A stable jet between the syringe needle assembly and the collector was obtained under these conditions. Fibers were collected on the ground electrode, consisting of glass slides placed above a grounded copper plate. All experiments were carried out at room temperature and various fiber mat thicknesses were obtained by adjusting time of spinning.

Electron microscopic analysis was performed using JEOL 6335F field emission scanning electron microscope (FESEM). Fluorescence microscopy studies were performed using a Zeiss Axiovert 200M Fluorescence Microscope with a 365 nm excitation wavelength and a 400-700 nm emission window. Steady-state fluorescence measurements were performed on a Fluorolog-3 spectrofluorometer. Colorimetric measurement were performed using a PR-670 SpectraScan colorimeter under laboratory 50 W UV lamp (λ=365 nm).

Throughout this application, various publications are referenced in order to more fully describe the state of the art to which these compounds and methods pertain. The disclosures of these publications are hereby incorporated by reference in their entireties to the same extent as if each independent publication, patent, and/or patent application was specifically and individually indicated to be incorporated by reference.

Reference is made herein to specific embodiments of the present invention. Each embodiment is provided by way of explanation of the invention, not as limitation of the invention. In fact, it will be apparent to those skilled in the art that various modifications and variations can be made in the present invention without departing from the scope or spirit of the invention. For instance, features illustrated or described as part of one embodiment may be incorporated into another embodiment to yield a further embodiment. Thus, it is intended that the present invention cover such modifications and variations as come within the scope of the appended claims and their equivalents.

Although specific embodiments of the various materials, cells and methods have been described, the present invention should not be construed so as to be limited to just those embodiments. It should be understood that the above examples are given only for the sake of showing that the materials, cells and methods can be made. The above materials, cells and methods can be generalized to encompass a broad genus. In this vein, any one or more features from any of the disclosed embodiments above can be combined with any one or more features from any other embodiment. Accordingly, the above written description is not meant to limit the invention in any way. Rather, the below claims define the invention.

1. A photovoltaic cell comprising an anode layer, a nucleic acid layer, and a cathode layer, wherein the nucleic acid layer lies between and in direct or indirect contact with both the anode layer and the cathode layer, and wherein the nucleic acid layer comprises a nucleic acid material and a plurality of donor and acceptor molecules that are spaced and oriented within the nucleic acid material in an arrangement for converting electromagnetic radiation into electrical energy.

2. The photovoltaic cell of claim 1, further comprising one or more intermediate layers comprising a hole blocking layer and/or an electron blocking layer, wherein the one or more intermediate layers lie between and in direct or indirect contact with the nucleic acid layer and the cathode layer or the nucleic acid layer and the anode layer.

3. The photovoltaic cell of claim 1, wherein the nucleic acid material comprises a nucleic acid molecule.

4. The photovoltaic cell of claim 1., wherein the nucleic acid material comprises a complex of a nucleic acid molecule and at least one of an ionic surfactant or a lipid with a cationic head group.

5. The photovoltaic cell of claim 3, wherein the nucleic acid molecule comprises DNA.

6. The photovoltaic cell of claim 4, wherein the ionic surfactant comprises a cationic quaternary ammonium salt.

7. The photovoltaic cell of claim 6, wherein the cationic quaternary ammonium salt comprises cetyl trimethylammonium chloride.

8. The photovoltaic cell of claim 1, wherein the nucleic acid material comprises a material in the form of a film, fiber, nanofiber, or non-woven mesh.

9. The photovoltaic cell of claim 1, wherein at least one of the donor or acceptor molecules is intercalated within the nucleic acid material.

10. The photovoltaic cell of claim 1, wherein at least one of the donor or acceptor molecules is groove-bound to the nucleic acid material.

11. The photovoltaic cell of claim 1, wherein at least one of the donor or acceptor molecules is ionically bound to the nucleic acid material.

12. The photovoltaic cell of claim 1, wherein at least one of the acceptor molecules and at least one of the donor molecules have lowest unoccupied molecular orbital (LUMO) energy levels such that the LUMO energy level of the at least one acceptor molecule is lower than the LUMO energy level of the at least one donor molecule.

13. The photovoltaic cell of claim 1, wherein the donor molecules are selected from the group consisting of organic dyes and pigments, oligomeric compounds, conductive polymers, and small molecules.

14. The photovoltaic cell of claim 13, wherein the donor molecules comprise oligothiophenes and the acceptor molecules comprise fullerenes or arenes.

15. The photovoltaic cell of claim 13, wherein the donor molecules comprise α-sexithiophene, α,ω-dialkylsexithiophene, or α,ω-dihexylsexithiophene and the acceptor molecules comprise Buckminsterfullerene, pentacene, or [6,6,]-phenyl-C₆₁-butyric acid methyl ester.

16. The photovoltaic cell of claim 1, wherein the donor molecules absorb ultraviolet radiation, near infrared radiation, infrared radiation, or visible radiation.

17. A method of producing electrical energy from electromagnetic radiation comprising:
(a) irradiating at least one donor molecule in the photovoltaic cell of claim 1, thereby placing at least one electron in the donor molecule into an excited state,
(b) transferring the excited electron from the donor molecule to an acceptor molecule, and
(c) transferring the excited electron from the acceptor molecule to a cathode,
whereby the transfer of the excited electron from the acceptor molecule to the cathode produces electrical energy.

18. The method of claim 17, wherein the step of irradiating the at least one donor molecule comprises irradiating the donor molecule with solar radiation.

19. The method of claim 17, wherein the step of irradiating the at least one donor molecule comprises irradiating the donor molecule with ultraviolet radiation, near infrared radiation, infrared radiation, or visible radiation.

20. A method of making a photovoltaic cell comprising:
(a) combining a plurality of donor and acceptor molecules with a nucleic acid material;
(b) processing the nucleic acid material to form a film, fiber, nanofiber, or non-woven mesh;
(c) placing a liquid electrolyte on the processed nucleic acid material;
(d) placing glass on the liquid electrolyte to create the photovoltaic cell, wherein the glass comprises a coating comprising a metal, and wherein the metal is selected from the group consisting of gold, platinum, and combinations thereof; and
(e) sealing the photovoltaic cell.
